(19) United States
(12) Patent Application Publication
(10) Pub. No.: US 2016/0375526 A1
(43) Pub. Date: Dec. 29, 2016

(54) Au-Sn-Ag BASED SOLDER ALLOY AND ELECTRONIC COMPONENT SEALED WITH THE SAME Au-Sn-Ag BASED SOLDER ALLOY, AND ELECTRONIC COMPONENT MOUNTING DEVICE

(71) Applicant: SUMITOMO METAL MINING CO., LTD., Tokyo (JP)

(72) Inventor: Takashi ISEKI, Tokyo (JP)

(73) Assignee: SUMITOMO METAL MINING CO., LTD., Tokyo (JP)

(21) Appl. No.: 15/102,990

(22) PCT Filed: Sep. 4, 2014
(86) PCT No.: PCT/JP2014/073349

§ 371 Date: Jun. 9, 2016

(30) Foreign Application Priority Data
Dec. 10, 2013 (JP) 2013-255224
Jun. 26, 2014 (JP) 2014-131682

(51) Int. Cl. B23K 35/30; H05K 3/34; H05K 1/18; C22C 5/02

(52) U.S. Cl. CPC B23K 35/3013; C22C 5/02; H05K 3/3463; H05K 1/18

(57) ABSTRACT

To provide an lead-free, Au—Sn—Ag based solder alloy for high temperature use that is sufficiently usable in bonding electronic components and electronic component mounting devices that are required to have very high reliability, such as crystal quartz devices, SAW filters and MEMS, yet at a particularly low cost, is excellent in processability and stress-relaxation property, and has high reliability.

Measures for Solution: Au—Sn—Ag based solder alloy characterized by containing Sn of 27.5 mass % or more but less than 33.0 mass % and containing Ag of 8.0 mass % or more but 14.5 mass % or less, wherein a balance being made up of Au, except for elements that are inevitably contained owing to manufacture procedure.

### TECHNICAL FIELD

The present invention relates to a lead-free solder alloy for high temperature, to be specific, a solder alloy containing Au as a main component and electronic components sealed with the same solder alloy.

### BACKGROUND ART

In recent years, regulations against chemicals harmful to the environment have come to be stricter and stricter. Solder materials to be used for bonding electronic components to substrates are not an exception to such regulations. While lead has been used as a main component of solder materials through the ages, it has already been designated as a regulated substance by RoHS directive and similar. Therefore, solder that does not contain lead (Pb) (hereinafter referred to as lead-free solder or unleaded solder) is under active development.

Solder to be used in bonding electronic components to substrates is roughly classified, by limit temperature for use, into a high temperature type (about 260° C.-400° C.) and a medium-to-low temperature type (about 140° C.-230° C.). Regarding the medium-to-low temperature type, solder containing Sn as a main component has been put into practical use as lead-free solder.

For example, as a lead-free solder material for medium-to-low temperature use, Japanese Patent KOKAI No. 11-77366 listed as Patent Document 1 discloses an unleaded solder alloy composition containing Sn as a main component, 1.0-4.0 wt % Ag, Cu of 2.0 wt % or less, Ni of 1.0 wt % or less, and P of 0.2wt % or less. Also, Japanese Patent KOKAI No. 8-215880 listed as Patent Document 2 discloses unleaded solder having an alloy composition containing 0.5-3.5 wt % Ag, 0.5-2.0 wt % Cu, and Sn as the balance.

On the other hand, with respect to lead-free solder materials for high temperature use, various organizations are engaged in development. For example, Japanese Patent KOKAI No. 2002-160089 listed as Patent Document 3 discloses a Bi/Ag brazing material with a melting temperature of 350-500° C. containing 30-80 at % Bi. Also, Japanese Patent KOKAI No. 2008-161913 listed as Patent Document 4 discloses a solder alloy composed of a eutectic alloy containing Bi to which a binary eutectic alloy is added and to which additive elements are further added. It argues that this solder, while being quaternary or multinary eutectic solder, allows of adjustment of liquidus temperature and reduction of non-uniformity.

As lead-free solder materials for high temperature use, which are expensive, Au—Sn alloys and Au—Ge alloys have already been used in crystal devices, SAW filters, and mount devices for electronic components such as MEMS. Au-20 mass % Sn alloy (this means that it is composed of 80 mass % Au and 20 mass % Sn; the same notation applies hereinafter also) has a eutectic composition, and has a melting point at 280° C. On the other hand, Au-12.5 mass % Ge alloy also has a eutectic composition, and has a melting point at 356° C.

Difference in use between Au—Sn alloys and Au—Ge alloys depends on such a difference in melting point. While being the high-temperature type, Au—Sn alloys are used for bonding of portions where temperature is relatively low. In cases of relatively high temperatures, Au—Ge alloys are used. However, Au-based alloys are much harder than Pb-based solder or Sn-based solder. In particular, Au—Ge alloys are very difficult to process into a sheet form because Ge is a semimetal. Accordingly, productivity and yield are rendered poor, to raise the cost.

Although not so much as Au—Ge alloys are, Au—Sn alloys also are difficult to process, and thus productivity and yield in processing them into preformed materials is poor. That is, although having a eutectic composition, Au-20 mass % Sn is yet constructed of intermetallic compounds. Therefore, with their dislocations being hard to move, Au—Sn alloys are hard to be deformed and thus are prone to generate cracks and burrs if rolled thin or punched out by a press. In spite of this drawback, since they are superior in view of melting point and processability for lead-free solder materials, Au—Sn alloys are frequently used for sealing crystal quartz devices, which are particularly required to have high reliability.

However, the Au-20 mass % Sn alloy requires extremely high material cost as compared with other solder materials, as a matter of course.

Therefore, for the purpose achieving inexpensive and highly usable Au—Sn alloys, there have been developed Au—Sn—Ag-based alloys as disclosed in Patent Documents 5 to 7, for example.

For the purpose of providing a brazing filler material and a piezoelectric device that have a relatively low melting point and thus are easy to handle, are excellent in strength and adhesion and are inexpensive, Japanese Patent KOKAI No. 2008-155221 listed as Patent Document 5 discloses a brazing filler material having a composition ratio (Au (wt %), Ag (wt %), Sn (wt %)) residing within a region surrounded by the points A1 to A5 below on a ternary composition diagram of Au, Ag and Sn:

Point A1 (41.8, 7.6, 50.5),

Point A2 (62.6, 3.4, 34.0),

Point A3 (75.7, 3.2, 21.1),

Point A4 (53.6, 22.1, 24.3),

Point A5 (30.3, 33.2, 36.6).

Also, for the purpose of providing lead-free solder that not only requires a smaller amount of Au addition than a conventional Au—Sn eutectic alloy does but also has a solidus temperature of 270° C. or higher, as well as for the purpose of providing a package that is excellent in heat cycle resistance and mechanical strength at the joint between the container body and the lid member, Japanese Patent No. 4305511 listed as Patent Document 6 discloses a high-temperature lead-free solder alloy for melt sealing having a composition containing 2-12 mass % Ag, 40-55 mass % Au, and Sn as the balance.

Also, for the purpose of providing a lead frame for brazing provided with a brazing filler material that has a low melting point, does not embrittle the lead frame made of Fe—Ni alloy, firms the bonding strength with its moderate degree of flow, and does not degrade corrosion resistance of the lead frame, Japanese Patent No. 2670098 listed as Patent Document 7 discloses a lead frame for brazing to which is attached, at the tips of the pins of the lead frame, a brazing filler material containing Ag to which 20-50 wt % Au and 10-20 wt % Ge or 20-40 wt % Sn are added.

### PRIOR ART DOCUMENTS

### Patent Documents

Patent Document 1: Japanese Patent KOKAI No. 11-77366

Patent Document 2: Japanese Patent KOKAI No. 8-215880

Patent Document 3: Japanese Patent KOKAI No. 2002-160089

Patent Document 4: Japanese Patent KOKAI No. 2008-161913

Patent Document 5: Japanese Patent KOKAI No. 2008-155221

Patent Document 6: Japanese Patent No. 4305511

Patent Document 7: Japanese Patent No. 2670098

### SUMMARY OF THE INVENTION

### Problems to be Solved by the Invention

Although various organizations are engaged in development of lead-free solder materials for high temperature use not limited to those of the above cited references, a versatile solder material available at a low cost has not yet been found. In general, since materials having relatively low heatproof temperature such as thermoplastic resin and thermosetting resin are commonly used for electronic components and substrates, it is necessary to control the working temperature to be lower than 400° C., desirably 370° C. or lower. However, for example in the case of the Bi/Ag brazing material disclosed in Patent Document 3, since the liquidus temperature is high, or to be 400-700° C., the working temperature during bonding is estimated to be higher than 400-700° C., which would exceed the heatproof temperature of the electronic components and the substrates to be bonded together.

Regarding Au—Sn-based solder and Au—Ge-based solder, such solder requires use of a large quantity of Au, which is very expensive, and thus comes to be very expensive as compared with Pb-based solder or Sn-based solder. Therefore, although such solder has been put into practical use, the application range is limited to soldering of portions where a high reliability is particularly required, such as crystal quartz devices, SAW filters and MEMS.

In addition, since Au-based solder is very hard and less processable, rolling it into a sheet form, for example, takes a long time and requires a special, less damageable material for the roller, to raise the cost. In press molding also, the hard and brittle nature of the Au-based solder easily generates cracks and burrs, to result in a poor yield as incomparable with those of other solder. Processing into a wire form also involves the similar problem; even by use of an extruder with very high pressure, the hardness of the solder renders extrusion speed low, to expect only one over a few hundreds productivity in reference to Pb-based solder.

To solve this problem of poor processability, there have been devised measures such as changing the state of Au-based solder into solder paste, yet to bring about other problems such as generation of voids and further increase in cost.

On the other hand, the Au—Sn—Ag based solder alloys disclosed in Patent Documents 5 to 7, which were developed for the purpose of solving various problems of Au-based solders including those in melting point, processability and cost as described above, also have the following problems, respectively.

Patent Document 5 refers to providing a brazing filler material and a piezoelectric device that are easy to handle as having a relatively low melting point, excellent in strength and adhesion, and inexpensive. Further, it also states that, by limiting the content ranges of Au, Sn and Ag respectively as shown above, although the content of Au is reduced from that %f conventional ones, equivalent properties for a sealant can be attained. However, Patent Document 5 does not refer to either a reason why the strength and adhesion of Au—Sn alloy is improved by addition of Ag or a reason why the equivalent properties (it can be interpreted as properties equivalent to Au—Ge alloys or Au—Sn alloys) for a sealant can be attained.

That is, there is no description about the reason why the equivalent properties to Au—Ge eutectic alloys or Au—Sn eutectic alloys, for example, the equivalent reliability can be attained, and thus the technical ground of the invention is unclear. Furthermore, by the reason described below, the invention of Patent Document 5 is supposed, far from being superior to Au—Ge eutectic alloys or Au—Sn eutectic alloys in properties including reliability, not to be able to attain even the properties equivalent to Au—Ge eutectic alloys or Au—Sn eutectic alloys all over the broad range of composition disclosed by Patent Document 5. Therefore, the art of Patent Document 5 is considered to be infeasible.

Below, the explanation is made of the reason why the art of Patent Document 5 is infeasible. Patent Document 5 discloses the composition ratio (Au (wt %), Ag (wt %), Sn (wt %)) residing within a region surrounded by the points A1 to A5 below on a ternary composition diagram of Au, Ag and Sn:

Point A1 (41.8, 7.6, 50.5),

Point A2 (62.6, 3.4, 34.0),

Point A3 (75.7, 3.2, 21.1),

Point A4 (53.6, 22.1, 24.3),

Point A5 (30.3, 33.2, 36.6).

However, this region is so wide a range that it is theoretically impossible to rather evenly attain desirable properties over the entire region of this wide range of composition.

For example, the point A3 and the point A5 differ in Au content by no less than 45.4 mass %. It is far from possible that, with a large difference in Au content, similar properties would be obtained at the point A3 and the point A5. A difference in composition ratio of Au, Sn and Ag would produce a difference in intermetallic compound, to result in a large difference in liquidus temperature and in solidus temperature. No less than 45.4 mass % difference in content of Au, which is least oxidizable, would produce a large difference in wettability, as a matter of course. As is apparent from FIG. 1 showing an Au—Sn—Ag ternary phase diagram, Au—Sn—Ag intermetallic compounds greatly vary depending on the combination of contents of Au, Sn and Ag. Therefore, kind and amount of intermetallic compounds formed at the time of bonding greatly varies, and thus similar excellent properties in processability and stress relaxation property could not be achieved over such a wide range of composition as disclosed by Patent Document 5.

In the brazing filler material disclosed by Patent Document 6, since 2-12 mass % Ag and 40-55 mass % Au are contained, the balance, or the content of Sn must be 33-58 mass %. However, such a large content of Su is liable to result in insufficient wettability because of oxidation progress. So far as thirty-and-several mass %, a good wettability is supposed to be assured in consideration of the Au-20 mass % Su alloy having been in practical use without problem, whereas, over 40 mass %, it is supposed to be difficult, in some cases, to assure good wettability. In particular, since this range of composition does not make a eutectic alloy, attaining a sufficient bonding reliability is difficult because of large crystal grains and so wide a gap between the liquidus temperature and the solidus temperature as causing separation of molten material in bonding.

The brazing filler material disclosed in Patent Document 7 has an Au content of 50 mass % at the maximum and thus greatly contributes to reduction of Au raw material. Since the Sn content is 40 mass % or less (or less than 40 mass %), a certain level of wettability may be assured. However, the object of the invention of Patent Document 7 is to prevent a lead frame made of a Fe—Ni alloy from being embrittled, to firm the bonding strength with a moderate degree of flow of the brazing filler, and to prevent the corrosion resistance of the lead frame from degradation.

The brazing filler material presented from these points of view by Patent Document 7 is unlikely to satisfy required properties for bonding semiconductor elements, such as stress relaxation caused by to expansion and shrinkage by heat. In particular, since this range of composition does not make a eutectic alloy, attaining a sufficient bonding reliability is difficult because of large crystal grains and so wide a gap between the liquidus temperature and the solidus temperature as causing fusion separation phenomenon in bonding. Furthermore, this brazing filler material is adapted to Fe—Ne alloys and thus would not form an alloy suitable for a substrate for junction, such as a metalized layer and Cu, of a semiconductor element. From this point of view also, it is obvious that this brazing filler material is not suitable for bonding with crystal quartz devices.

In this way, since the Au—Sn—Ag based solder alloys disclosed by Patent Documents 5-7 have the respective problems as described above, they fail to be lead-free Au—Sn—Ag based solder alloys for high temperature use that have excellent properties with respect to all of the aspects including cost, processability, stress relaxation property and reliability.

The present invention is made in view of such circumstances, and its object is to provide, at a particularly low cost, a lead-free Au—Sn—Ag based solder for high temperature use that is sufficiently usable in bonding electronic components and electronic component mounting devices that are required to have very high reliability, such as crystal quartz devices, SAW filters and MEMS, and is excellent in processability, stress relaxation property and reliability.

### Measures to Solve the Problems

Therefore, in order to attain the above-mentioned object, an Au—Sn—Ag based solder alloy according to the present invention is characterized by containing Sn of 27.5 mass % or more but less than 33.0 mass % and containing Ag of 8.0 mass % or more but 14.5 mass % or less, wherein the balance is made up by Au except for elements that are inevitably contained owing to a procedure for manufacturing.

Also, according to the present invention, it is preferable that one or more elements out of Al, Cu, Ge, In, Mg, Ni, Sb, Zn and P is further contained, wherein, if Al is contained, a content thereof is 0.01 mass % or more but 0.8 mass % or less; if Cu is contained, a content thereof is 0.01 mass % or more but 1.0 mass % or less; if Ge is contained, a content thereof is 0.01 mass % or more but 1.0 mass % or less; if In is contained, a content thereof is 0.01 mass % or more but 1.0 mass % or less; if Mg is contained, a content thereof is 0.01 mass % or more but 0.5 mass % or less; if Ni is contained, a content thereof is 0.01 mass % or more but 0.7 mass % or less; if Sb is contained, a content thereof is 0.01 mass % or more but 0.5 mass % or less; if Zn is contained, a content thereof is 0.01 mass % or more but 5.0 mass % or less; and if Pis contained, a content thereof is 0.500 mass % or less.

Also, according to the present invention, it is preferable that Sn of 29.0 mass % or more but 32.0 mass % or less is contained and Ag of 10.0 mass % or more but 14.0 mass % or less is contained, wherein a balance is made up by Au except for elements that are inevitably contained owing to the procedure for manufacturing.

Also, according to the present invention, it is preferable that at least a part of a metallic structure is a lamellar structure.

Also, according to the present invention, it is preferable that a metallic structure is a lamellar structure and occupies 90 vol % or more.

On the other hand, an electronic component according to the present invention is characterized by being sealed up by use of the above Au—Sn—Ag based solder alloy.

Also, an electronic component mounting device according to the present invention is characterized by mounting thereon an electronic component sealed up by use of the above Au—Sn—Ag based solder alloy.

### Effect of the Invention

According to the present invention, it is possible to provide, at a lower cost than conventional Au-based solder requires, a solder alloy used for electronic components and electronic component mounting devices that are required to have very high reliability, such as crystal quartz devices, SAW filters and MEMS. That is, the solder alloy of the present invention is based on a eutectic metal, and thus is excellent in processability with refined crystals and a crystalline structure formed into a lamellar structure. In addition, since the maximum Au content is 61 mass %, further cost reduction can be achieved, while an Au-base solder having sufficient wettability and reliability can be provided. In addition, by further containing fourth and subsequent-order elements, the alloy can meet various requirements. Therefore, the contribution to industries is very large.

### BRIEF DESCRIPTION OF THE DRAWINGS

FIG. 1. is an Au—Sn—Ag ternary phase diagram at 370° C.

FIG. 2. is a schematic diagram of a sample for evaluation of shear strength test, showing a state where a Si chip is soldered, by use of a solder alloy as each sample, on a Cu substrate having a Ni layer (plating).

FIG. 3. is a schematic diagram of a sample for evaluation of wettability test, showing a state where a solder alloy as each sample is soldered to a Cu substrate having a Ni layer (plating).

FIG. 4. is a schematic diagram of a section of a container for sealing sealed with a solder alloy as each sample.

### MODE FOR CARRYING OUT THE INVENTION

Hereinafter, the Au—Sn—Ag based solder alloy of the present invention will be explained in detail. The composition of the Au—Sn—Ag based solder alloy of the present invention is characterized by containing Sn of 27.5 mass % or more but less than 33.0 mass % and containing Ag of 8.0 mass % or more but 14.5 mass % or less, wherein the balance is made up by Au except for elements that are inevitably contained owing to a procedure for manufacturing.

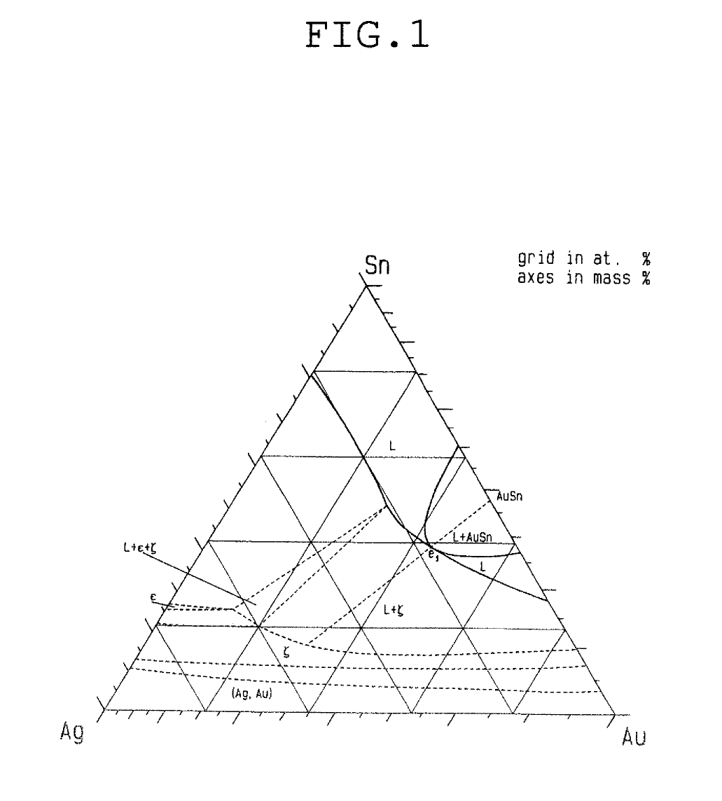

As a result of devotion to the extensive researches, the present inventor has finally found that a Au—Sn—Ag based solder alloy having a basic composition near the ternary eutectic point (the point “e₁” in the Au—Sn—Ag ternary phase diagram of FIG. 1) of Au, Sn and Ag is particularly excellent as a lead-free Au-based solder in various properties. That is, if a composition range in a vicinity of the ternary eutectic point of Au, Sn and Ag is satisfied, it produces a solder alloy that is inevitably softer than an Au—Sn alloy and thus is excellent in processability and stress relaxation property, and further, has a wettability sufficient for practical use. In addition, the significant reduction in Au content by substitution of Sn and Ag for a part of Au, which is expensive, makes it possible to drastically reduce the cost.

In addition, for further improvement of properties, the solder alloy of the present invention is allowed to contain, as fourth and subsequent-order elements, one or more elements out of Al, Cu, Ge, In, Mg, Ni, Sb, Zn and P. It is preferred that, if Al is contained, a content thereof is 0.01 mass % or more but 0.8 mass % or less; if Cu is contained, a content thereof is 0.01 mass % or more but 1.0 mass % or less; if Ge is contained, a content thereof is 0.01 mass % or more but 1.0 mass % or less; if In is contained, a content thereof is 0.01 mass % or more but 1.0 mass % or less; if Mg is contained, a content thereof is 0.01 mass % or more but 0.5 mass % or less; if Ni is contained, a content thereof is 0.01 mass % or more but 0.7 mass % or less; if Sb is contained, a content thereof is 0.01 mass % or more but 0.5 mass % or less; if Zn is contained, a content thereof is 0.01 mass % or more but 5.0 mass % or less; and if P is contained, a content thereof is 0.500 mass % or less.

The solder alloy of the present invention has a basic composition at Au=57.2 mass %, Sn=30.8 mass %, and Ag=12.0 mass % (in at % expression, Au=43.9 at %, Sn=39.3 at %, and Ag=16.8 at %), which is an Au—Sn—Ag ternary eutectic point. Thereby, in solidification of molten alloy at the ternary eutectic point, crystals are refined and a crystalline structure is formed into a lamellar structure, to remarkably improve processability and stress relaxation property. Also, according to the present invention, since there is basically no gap or a little gap between the liquidus temperature and the solidus temperature, separation of molten material is unlikely to occur. Furthermore, since a large amount of Sn and Ag can be contained, a reduction of Au content is made possible, to attain a significant cost-saving effect.

Furthermore, by containing a large amount of Ag, which has a high reactivity and a poor oxidizability, it is possible to attain favorable wettability and bondability. Hereinafter, elements of the solder alloy of the present invention will be explained in further detail.

### <Au>

Au is a main component of the solder alloy of the present invention, and is an essential element, as a matter of course. Since Au is very slightly oxidizable, it is most suitable, in view of properties, as solder for bonding and sealing electronic components that are required to have high reliability. Therefore, Au-based solder is frequently used for sealing crystal quartz devices and SAW filters. The solder alloy of the present invention also is based on Au, and provides solder that belongs to the technical fields where such high reliability is required.

However, since Au is a very expensive metal, it is better, in view of cost, to use it as little as possible. Therefore, Au is rarely used for electronic components that are required to have a common level of reliability. The solder alloy of the present invention is made as an alloy having a composition near the Au—Sn—Ag ternary eutectic point, to be comparable with Au-20 mass % Sn solder or Au-12.5 mass % Ge solder in view of properties such as wettability and bondability, to have improved flexibility and processability, and to contribute to cost reduction with a reduced Au content.

### <Sn>

Sn is an essential element and a basic element in the alloy of the present invention. Au—Sn solder alloys are usually used at compositions near of the eutectic point, or compositions near Au-20 mass % Sn, thereby to have a solidus temperature at 280° C., to be finely crystalized, and to rather attain flexibility. In spite of its being a eutectic alloy, the Au-20 mass % Sn alloy is constructed of an intermetallic compound Au₁Sn₁ and an intermetallic compound Au₅Sn₁ and thus is hard and brittle. Therefore, such alloys are difficult to process. For example, in a case of processing them into sheet form by rolling, thinning proceeds only little by little, to result in a low productivity, and a plenty of cracks appear during rolling, to result in a poor yield, whereas, this hard and brittle nature of intermetallic compounds is normally unchangeable. Although Au—Sn solder alloys are such hard and brittle materials, they are used for high-reliability applications, because they are hard to oxidize and thus are excellent in wettability and reliability.

The solder alloy of the present invention is constructed of an intermetallic compound Au₁Sn₁ and ζ phase, and is based on a composition near a eutectic point. ζ phase is an Au—Sn—Ag intermetallic compound having a composition ratio with respect to at % of Au:Sn:Ag=30.1:16.1:53.8 (reference document: “Ternary Alloys, A Comprehensive Compendium of Evaluated Constitutional Data and Phase Diagrams, Edited by G. Petzow and Effenberg, VCH). Since this ζ phase rather has a flexibility and a lamellar structure is formed upon the basic composition being near the eutectic point, the solder alloy of the present invention is excellent in processability and stress relaxation property. In addition, by lowering the melting point, it attains a eutectic temperature at 370° C., which is comparable with a eutectic temperature of Au—Ge alloys. To have an appropriate melting point for a solder alloy of high temperature use is also one of excellent points of the solder alloy of the present invention.

The Sn content is 27.5 mass % or more and less than 33.0 mass %. If less than 27.0 mass %, crystal grains grow large, the effect of flexibility and improved processability is not sufficiently enjoyed, and too wide a gap between the liquidus temperature and the solidus temperature causes separation of molten material. Further, since Au content is liable to be high, the cost saving effect is limited. On the other hand, if the Sn content is 33.0 mass % or more, the composition is so far off the eutectic point that problems of large crystal grains and too wide a gap between the liquidus temperature and the solidus temperature occur. In addition, too large a Sn content would probably raise oxidizability, and thus the alloy loses a good wettability, which must be a characteristic feature of Au-based solder, to have a difficulty in attaining a high bonding reliability.

In the case of Sn content being 29.0 mass % or more and 32.0 mass % or less, the composition is much closer to the eutectic point and is preferable, for crystal grain refining effect is achieved and separation of molten material barely occurs.

### <Ag>

Ag is an essential element in the solder of the present invention, and is an element indispensable for making the solder as a ternary eutectic alloy. By making the alloy at a composition near the Au—Sn—Ag ternary eutectic point, it is possible to attain excellent flexibility and processability, stress relaxation property, and an appropriate melting point, and moreover, drastic cost reduction can be achieved by significant reduction of Au content. Ag has an effect on improvement of wettability. That is, Ag has a good reactivity with elements such as Cu and Ni, which are used on the uppermost surfaces of substrates, and thus can improve wettability. Needless to say, Ag is excellent in reactivity with Ag- or Au-metallized layers, which are frequently used at junctions of semiconductor elements.

The Ag content at which the excellent effects as stated above are exerted is 8.0 mass % or more and 14.5 mass % or less. If less than 8.0 mass %, the composition is so far off the eutectic point, to make it difficult to achieve good bonding because of too high a liquidus temperature or large crystal grains. On the other hand, if 14.5 mass % is exceeded, the liquidus temperature is raised high, to cause separation of molten material or troubles given by large crystal grains.

In the case of Ag content being 10.0 mass % or more and 14.0 mass % or less, the composition is much closer to the eutectic point and is preferable, for the effect by addition of Ag is more prominent.

### <Al, Ge, Mg>

Al, Ge, and Mg are elements that are allowed to be contained, according to the present invention, for improvement or adjustment of various properties. The main effect by addition of these elements is the same, that is, improvement of wettability.

Al is solid-soluble in Au up to several mass %, is solid-soluble in Sn as a trace, and is solid-soluble in Ag up to several mass %. In this way, Al, in the solid state, is dissolved into the Au—Sn—Ag based alloy as a small amount. On the other hand, since it is more oxidizable than Au, Sn and Ag, Al is the first to oxidize in the molten state in bonding, to form a thin oxide film on the solder surface, and improves wettability by retarding progress of oxidation of the matrix. The Al content at which this wettability improving effect is exerted is 0.01 mass % or more and 0.8 mass % or less. If less than 0.01 mass %, the effect by addition of Al substantially fails to manifest itself because of too low the content. If 0.8 mass % is exceeded, the oxide film grows so thick as even to degrade wettability. Al content of 0.1 mass % or more and 0.5 mass % or less is preferable, for the effect by addition of Al manifests itself more prominently.

Ge forms a eutectic alloy of solid solution with Au, is barely solid-soluble in Sn, and forms the eutectic alloy of solid solution with Ag. For preventing embrittlement of the solder alloy, it is preferred to contain Ge not so match an amount as to generate intermetallic compounds with Sn. The mechanism by which Ge improves wettability is as follows. Ge has a relatively small specific gravity and thus rather comes up to the surface in molten solder, to oxidize to form a thin oxide film, and improves wettability by retarding progress of oxidation of the matrix. The Ge content at which such an effect is exerted is 0.01 mass % or more and 1.0 mass % or less. If Ge content is less than 0.01 mass %, this effect fails to manifest itself because of too low the content. If 1.0 mass % is exceeded, too high the content causes embrittlement of the solder alloy or monotectoid reaction of Ge, to degrade bondability and reliability.

Mg forms an intermetallic compound AuMg₃ with Au, is barely solid-soluble in Sn but forms an intermetallic compound Mg₂Sn with Sn, and is solid-soluble in Ag up to about 6 mass %. While the main effect by addition of Mg is improvement of wettability, a large amount of intermetallic compounds formed of Mg as stated above would embrittle the alloy and thus a large amount of Mg should not be contained. The mechanism by which Mg improves wettability is as follows. Mg is highly oxidizable and thus, by a small amount of addition, it makes itself oxidize, to improve wettability. Although a large amount of it should not be contained, as stated above, Mg has a very intense reducing capability and thus even a small amount of addition is effective. The Mg content is 0.01 mass % and more and 0.5 mass % or less. If less than 0.1 mass %, the effect by addition substantially fails to manifest itself because of too low the content. If 0.5 mass % is exceeded, an intermetallic compound AuMg₃ and an intermetallic compound Mg₂Sn, which are brittle, are formed as stated above, to result in extreme degradation of reliability.

### <Cu, In, Sb>

Cu, In, and Sb are elements that are allowed to be contained, according to the present invention, for improvement or adjustment of various properties. The main effect by addition of these elements is the same, that is, prevention of crack development in solder.

Cu forms an intermetallic compound AuCu with Au, and is solid-soluble in Sn and in Ag. An intermetallic compound, if growing beyond an allowable range or containing large ones, comes to be brittle, to cause, for example, a tilt of a mounted chip, and thus should be avoided. However, if an appropriate amount of it is formed and finely dispersed throughout the solder, the intermetallic compound enhances tensile strength of the solder, to have the effect of crack prevention. To be specific, if the intermetallic compound is dispersed throughout the solder, the end of a crack, which is developing through the solder because of thermal stress or so, is met by the intermetallic compound and the crack development is stopped by this hard intermetallic compound. This mechanism is basically the same as the mechanism by which an intermetallic compound Ag₃Sn in Pb—Sn—Ag based solder has the effect of crack prevention, and accordingly the effect of reliability improvement. The Cu content at which such an excellent effect is exerted is 0.01 mass % or more and 1.0 mass % or less. If Cu content is less than 0.01 mass %, the effect fails to manifest itself because of too low the content. If 1.0 mass % is exceeded, the intermetallic compound is formed beyond an allowable amount, to make the alloy hard and brittle, to degrade reliability.

In (indium) is barely solid-soluble in Au, is solid-soluble in Sn up to about 1 mass %, and is solid-soluble in Ag up to twenty-and-several mass %. With In being contained in the solder alloy, tensile strength is favorably enhanced because of solid solution strengthening, and thus crack development is prevented. The In content at which such an effect is exerted is 0.01 mass % or more and 1.0 mass % or less. If In content is less than 0.01 mass %, the effect fails to manifest itself because of too low the content. If 1.0 mass % is exceeded, the strength is excessively enhanced, to degrade the stress relaxation effect, and thus it may happen that, when a thermal stress or the like is applied to a chip assembly, the solder fails to relax the stress, to let the chip break.

Sb forms, with Au, a eutectic alloy constructed of Au solid solution and AuSb₂, is solid-soluble in Sn as a trace, and is solid-soluble in Ag up to about 7 mass %. The effect by addition of Sb is prevention of crack development in solder. The mechanism of this effect is similar to the case of In. That is, with Sb being contained in the solder alloy, tensile strength is favorably enhanced because of solid solution strengthening, and thus crack development is prevented. The Sb content at which such an effect is exerted is 0.01 mass % or more and 0.5 mass % or less. If Sb content is less than 0.01 mass %, the effect fails to manifest itself because of too low the content. If 0.5 mass % is exceeded, the strength is excessively enhanced, and thus it may happen that, when the solder contracts as cooled after chip bonding, the chip yields to hardness of the solder, to break.

### <Ni>

Ni is one of elements that are allowed to be contained, according to the present invention, for improvement or adjustment of various properties. The main effect by Ni is improvement of bonding reliability etc. owing to refinement of crystals. Ni is, yet as a trace, solid-soluble in Sn and in Ag. In a situation where molten solder containing such a trace of Ni is cooled to solidify, Ni, which has a high melting point, first grows as dispersing all over the solder, and then around Ni as nuclei, crystals grow. As a result, the solder crystals come to have refined structure. The solder, as finely crystallized in this way, is improved in tensile strength, and much more retards development of cracks, for cracks would basically develop along grain boundaries. Accordingly, reliability is improved at a heat cycle test or so. The Ni content at which such an effect is exerted is 0.01 mass % or more and 0.7 mass % or less. If Ni content is less than 0.01 mass %, the effect fails to manifest itself because of too low the content. If 0.7 mass % is exceeded, crystal grains grow even large, to degrade reliability.

### <Zn>

Zn is one of elements that are allowed to be contained, according to the present invention, for improvement or adjustment of various properties. The main effect by Zn is improvement of wettability and bondability. Zn is solid-soluble in Au up to about 4 mass %, forms, with Sn, a eutectic alloy constructed of solid solutions, and is solid-soluble in Ag at least 20 mass %. Zn, which is solid-solved and forms a eutectic alloy in the solder alloy in this way, does not form a hard and brittle intermetallic compound beyond an allowable range and thus does not significantly affect mechanical properties. Since Zn has a high reactivity with substances such as Cu, which is a main component of substrates, it improves wettability and bondability. That is, Zn in the solder reacts with Cu to be alloyed therewith as wetting and spreading on the substrate, to form a firm alloy layer. The Zn content at which such an effect is exerted is 0.01 mass % or more and 5.0 mass % or less. If Zn content is less than 0.01 mass %, the effect substantially fails to manifest itself because of too low the content. If 5.0 mass % is exceeded, the alloy layer is formed too thick or an oxide film on the solder surface is made too thick by easily oxidizable Zn, to cause degradation of wettability. The degradation of wettability would cause insufficient generation of the alloy layer or a large number of voids, and accordingly degradation of properties such as bonding strength also would be noticeable.

### <P>

P is one of elements that are allowed to be contained, according to the present invention, for improvement or adjustment of various properties. The effect by P oxidize itself is improvement of wettability and bondability. The mechanism by which P improves wettability is as follows. P, as having an intense reducing capability, prevents oxidization of the solder alloy surface as well as reduces the substrate surface by oxidizing itself, to improve wettability. Although Au-based solder generally is hard to oxidize and excellent in wettability, it cannot remove oxide on the bonding surface. However, P is capable of removing not only an oxide film on the solder surface but also an oxide film on the bonding surface of the substrate or the like. Such removal of oxide films on the solder surface and on the bonding surface effects also in decreasing gaps (voids) formed by oxide films. This effect by P further improves properties such as bondability and reliability. Since P vaporizes as soon as it is turned into an oxide by reducing the solder alloy and the substrate, and is swept away by the atmospheric gas, it does not remain in the solder or the substrate. Therefore, residues of P never affect reliability etc, and thus P is an excellent element in this regard also. In the case where the solder alloy of the present invention contains P, the P content of 0.500 mass % or less is preferable. Since P has a very intense reducing capability, containing a trace of it makes it possible to improve wettability, whereas containing P more than 0.500 mass % does not further change the wettability improving effect. Such an excessive addition of P would generate a large amount of gas of P and P oxide, to raise void rate, or would allow P to cause monotectoid reaction as forming a brittle phase, to embrittle the solder bonding portion and degrade reliability and the like.

### EMBODIED EXAMPLES

The present invention will be explained below in further detail in reference to the concretely embodied examples. The present invention should not be construed as being limited in any way by these examples.

First, as raw materials, Au, Sn, Ag, Al, Cu, Ge, In, Mg, Ni, Sb, Zn and P each having a 99.9 mass % purity were prepared. Regarding the materials in the form of large flakes or bulks, they were cut or crushed into pieces as fine as 3 mm or smaller, so that each molten alloy should be homogeneous without variation in composition depending on sampling points. Then, predetermined amounts of the raw materials corresponding to each of Samples 1 to 65 shown in Table 1 were weighed and put in a graphite crucible adapted for high-frequency melting furnace. It is noted that Sample 46 and Sample 52 were of Au-20 mass % Sn alloy and Sample 47 and Sample 53 were of Au-12.5 mass % Ge alloy.

The crucible containing the row materials was put in the high-frequency melting furnace, and nitrogen was flowed at a flow rate of 0.7 L/min or higher per 1 kg of the raw materials for preventing oxidation. At this state, the melting furnace was turned on, to make the row materials heated and melted. Once the metals started melting, the materials were stirred with a mixing bar to be homogeneous without a local variation in composition. Then, after confirming that the materials were completely fused, the high-frequency power supply was turned off, the crucible was promptly taken out, and the molten metal in the crucible was poured into a mold of a master solder alloy. Regarding molds, there were used those to obtain plate-shaped alloys of 5 mm thickness×42 mm width×260 mm length, adapted for rolling for manufacturing sheets and punched-out products, and those to obtain column-shaped alloys with 27 mm diameter, adapted for liquid atomization for manufacturing balls.

In this way, master solder alloys of Samples 1 to 65 were fabricated all in the same manner except for different mixing ratio of raw materials. For each of the master solder alloys of Samples 1 to 65, composition analysis was carried out with an ICP emission spectrometer (SHIMAZU S-8100). The acquired results of analysis and the shape of the master alloys are shown in Table 1 below.

TABLE 1

| | Shape of | Composition [mass %] | | | | | | | | | | | |
|---|---|---|---|---|---|---|---|---|---|---|---|---|---|
| Sample | Master Alloy | Au | Sn | Ag | Al | Cu | Ge | In | Mg | Ni | Sb | Zn | P |
| 1 | Plate | 60.3 | 27.7 | 12 | 0 | 0 | 0 | 0 | 0 | 0 | 0 | 0 | 0 |
| 2 | Plate | 58.8 | 29.2 | 12 | 0 | 0 | 0 | 0 | 0 | 0 | 0 | 0 | 0 |
| 3 | Plate | 57 | 30.8 | 12.2 | 0 | 0 | 0 | 0 | 0 | 0 | 0 | 0 | 0 |
| 4 | Plate | 56 | 31.9 | 12.1 | 0 | 0 | 0 | 0 | 0 | 0 | 0 | 0 | 0 |
| 5 | Plate | 55.1 | 32.9 | 12 | 0 | 0 | 0 | 0 | 0 | 0 | 0 | 0 | 0 |
| 6 | Plate | 61 | 30.8 | 8.2 | 0 | 0 | 0 | 0 | 0 | 0 | 0 | 0 | 0 |
| 7 | Plate | 59.2 | 30.7 | 10.1 | 0 | 0 | 0 | 0 | 0 | 0 | 0 | 0 | 0 |
| 8 | Plate | 57.2 | 30.8 | 12 | 0 | 0 | 0 | 0 | 0 | 0 | 0 | 0 | 0 |
| 9 | Plate | 55.8 | 30.9 | 13.3 | 0 | 0 | 0 | 0 | 0 | 0 | 0 | 0 | 0 |
| 10 | Plate | 54.8 | 30.8 | 14.4 | 0 | 0 | 0 | 0 | 0 | 0 | 0 | 0 | 0 |
| 11 | Column | 60.4 | 27.6 | 12 | 0 | 0 | 0 | 0 | 0 | 0 | 0 | 0 | 0 |
| 12 | Column | 58.8 | 29.1 | 12.1 | 0 | 0 | 0 | 0 | 0 | 0 | 0 | 0 | 0 |
| 13 | Column | 57.1 | 30.8 | 12.1 | 0 | 0 | 0 | 0 | 0 | 0 | 0 | 0 | 0 |
| 14 | Column | 56 | 31.8 | 12.2 | 0 | 0 | 0 | 0 | 0 | 0 | 0 | 0 | 0 |
| 15 | Column | 55.1 | 32.9 | 12 | 0 | 0 | 0 | 0 | 0 | 0 | 0 | 0 | 0 |
| 16 | Column | 61.1 | 30.8 | 8.1 | 0 | 0 | 0 | 0 | 0 | 0 | 0 | 0 | 0 |
| 17 | Column | 59.1 | 30.7 | 10.2 | 0 | 0 | 0 | 0 | 0 | 0 | 0 | 0 | 0 |
| 18 | Column | 57.1 | 30.9 | 12 | 0 | 0 | 0 | 0 | 0 | 0 | 0 | 0 | 0 |
| 19 | Column | 55.8 | 30.9 | 13.3 | 0 | 0 | 0 | 0 | 0 | 0 | 0 | 0 | 0 |
| 20 | Column | 54.8 | 30.8 | 14.4 | 0 | 0 | 0 | 0 | 0 | 0 | 0 | 0 | 0 |
| 21 | Column | 57.1 | 30.8 | 12 | 0.1 | 0 | 0 | 0 | 0 | 0 | 0 | 0 | 0 |
| 22 | Column | 56.5 | 30.8 | 12 | 0.7 | 0 | 0 | 0 | 0 | 0 | 0 | 0 | 0 |
| 23 | Column | 57.1 | 30.7 | 12.1 | 0 | 0.1 | 0 | 0 | 0 | 0 | 0 | 0 | 0 |
| 24 | Column | 56.4 | 30.8 | 12 | 0 | 0.8 | 0 | 0 | 0 | 0 | 0 | 0 | 0 |
| 25 | Column | 57 | 30.8 | 12 | 0 | 0 | 0.2 | 0 | 0 | 0 | 0 | 0 | 0 |
| 26 | Column | 56.2 | 30.9 | 12 | 0 | 0 | 0.9 | 0 | 0 | 0 | 0 | 0 | 0 |
| 27 | Column | 57.1 | 30.8 | 12 | 0 | 0 | 0 | 0.1 | 0 | 0 | 0 | 0 | 0 |
| 28 | Column | 56.3 | 30.8 | 12 | 0 | 0 | 0 | 0.9 | 0 | 0 | 0 | 0 | 0 |
| 29 | Column | 57.1 | 30.8 | 12 | 0 | 0 | 0 | 0 | 0.1 | 0 | 0 | 0 | 0 |
| 30 | Column | 56.9 | 30.7 | 12 | 0 | 0 | 0 | 0 | 0.4 | 0 | 0 | 0 | 0 |
| 31 | Column | 57.1 | 30.8 | 12 | 0 | 0 | 0 | 0 | 0 | 0.1 | 0 | 0 | 0 |
| 32 | Column | 56.5 | 30.8 | 12.1 | 0 | 0 | 0 | 0 | 0 | 0.6 | 0 | 0 | 0 |
| 33 | Column | 57.1 | 30.8 | 12 | 0 | 0 | 0 | 0 | 0 | 0 | 0.1 | 0 | 0 |
| 34 | Column | 56.7 | 30.8 | 12.1 | 0 | 0 | 0 | 0 | 0 | 0 | 0.4 | 0 | 0 |
| 35 | Column | 56.9 | 30.8 | 12 | 0 | 0 | 0 | 0 | 0 | 0 | 0 | 0.3 | 0 |
| 36 | Column | 52.2 | 30.8 | 12.2 | 0 | 0 | 0 | 0 | 0 | 0 | 0 | 4.8 | 0 |
| 37 | Column | 57.185 | 30.8 | 12 | 0 | 0 | 0 | 0 | 0 | 0 | 0 | 0 | 0.015 |
| 38 | Column | 56.722 | 30.8 | 12 | 0 | 0 | 0 | 0 | 0 | 0 | 0 | 0 | 0.478 |
| 39 | Column | 56.6 | 30.8 | 12 | 0.3 | 0.2 | 0.1 | 0 | 0 | 0 | 0 | 0 | 0 |
| 40 | Column | 56.5 | 30.8 | 12.1 | 0 | 0 | 0 | 0.1 | 0.2 | 0.3 | 0 | 0 | 0 |
| 41 | Column | 56.6 | 30.8 | 12 | 0 | 0 | 0 | 0 | 0 | 0 | 0.2 | 0.2 | 0.2 |
| *42 | Plate | 62.6 | 25.4 | 12 | 0 | 0 | 0 | 0 | 0 | 0 | 0 | 0 | 0 |
| *43 | Plate | 51.4 | 36.5 | 12.1 | 0 | 0 | 0 | 0 | 0 | 0 | 0 | 0 | 0 |
| *44 | Plate | 61.8 | 30.8 | 7.4 | 0 | 0 | 0 | 0 | 0 | 0 | 0 | 0 | 0 |
| *45 | Plate | 52.3 | 30.8 | 16.9 | 0 | 0 | 0 | 0 | 0 | 0 | 0 | 0 | 0 |
| *46 | Plate | 80 | 20 | 0 | 0 | 0 | 0 | 0 | 0 | 0 | 0 | 0 | 0 |
| *47 | Plate | 87.5 | 0 | 0 | 0 | 0 | 12.5 | 0 | 0 | 0 | 0 | 0 | 0 |
| *48 | Column | 62.7 | 25.3 | 12 | 0 | 0 | 0 | 0 | 0 | 0 | 0 | 0 | 0 |
| *49 | Column | 51.3 | 36.7 | 12 | 0 | 0 | 0 | 0 | 0 | 0 | 0 | 0 | 0 |
| *50 | Column | 61.9 | 30.8 | 7.3 | 0 | 0 | 0 | 0 | 0 | 0 | 0 | 0 | 0 |
| *51 | Column | 52.3 | 30.9 | 16.8 | 0 | 0 | 0 | 0 | 0 | 0 | 0 | 0 | 0 |
| *52 | Column | 80 | 20 | 0 | 0 | 0 | 0 | 0 | 0 | 0 | 0 | 0 | 0 |
| *53 | Column | 87.5 | 0 | 0 | 0 | 0 | 12.5 | 0 | 0 | 0 | 0 | 0 | 0 |
| *54 | Column | 55.7 | 30.8 | 12 | 1.5 | 0 | 0 | 0 | 0 | 0 | 0 | 0 | 0 |
| *55 | Column | 55.4 | 30.8 | 12 | 0 | 1.8 | 0 | 0 | 0 | 0 | 0 | 0 | 0 |
| *56 | Column | 55.6 | 30.9 | 12 | 0 | 0 | 1.5 | 0 | 0 | 0 | 0 | 0 | 0 |
| *57 | Column | 55.3 | 30.8 | 12 | 0 | 0 | 0 | 1.9 | 0 | 0 | 0 | 0 | 0 |
| *58 | Column | 55.9 | 30.8 | 12.2 | 0 | 0 | 0 | 0 | 1.1 | 0 | 0 | 0 | 0 |
| *59 | Column | 55.9 | 30.7 | 12.1 | 0 | 0 | 0 | 0 | 0 | 1.3 | 0 | 0 | 0 |
| *60 | Column | 56 | 30.8 | 12 | 0 | 0 | 0 | 0 | 0 | 0 | 1.2 | 0 | 0 |
| *61 | Column | 49.8 | 30.8 | 12 | 0 | 0 | 0 | 0 | 0 | 0 | 0 | 7.4 | 0 |
| *62 | Column | 56.162 | 30.8 | 12 | 0 | 0 | 0 | 0 | 0 | 0 | 0 | 0 | 1.038 |
| *63 | Column | 55.1 | 30.9 | 12.1 | 0.3 | 1.5 | 0.1 | 0 | 0 | 0 | 0 | 0 | 0 |
| *64 | Column | 55.6 | 30.8 | 12 | 0 | 0 | 0 | 0.1 | 1.2 | 0.3 | 0 | 0 | 0 |
| *65 | Column | 50.5 | 30.8 | 12 | 0 | 0 | 0 | 0 | 0 | 0 | 0.2 | 6.3 | 0.2 |

(Note)
The samples marked with * in the table are reference examples.

Next, regarding the plate-shaped master solder alloys of Samples 1 to 10 and 42 to 47, each of them was rolled by a warm rolling machine into a sheet, and the incidence of cracks was examined to give the result as the first evaluation of processability. Then, from this sheet-shaped sample, preform materials (punched-out products) were punched out into rectangular pieces of 0.6 mm×0.5 mm, and the pass rate of the punched out products was examined to give the result as the second evaluation of processability. Processing methods of samples and respective evaluations are explained below, and the acquired results of evaluations are shown in Table 2.

### <Production Method of Sheet (Evaluation 1 of Processability)>

Each of the prepared plate-shaped master alloys of 5 mm thickness×42 mm width×260 mm length was rolled with the warm rolling machine. Rolling conditions were the same for all the samples. The number of times of rolling was 5, the rolling speed was 15-30 cm/sec., Roll temperature was 260° C., and each sample was rolled thinner down to 30.0±1.2 μm through five times of rolling. After the rolling of each sample, the first evaluation of processability was made such that, per 10 m of the sheet, a case where no crack or burr was generated was ranked as “∘”, a case where 1-3 cracks or burrs were generated was ranked as “Δ”, and a case where 4 or more cracks or burrs were generated was ranked as “×”.

### <Punching (Evaluation 2 of Processability)>

Each of the samples as processed into sheet was punched, to produce punched-out products.

From each sample, 1000 pieces of punched-out products having a rectangular shape of 0.6 mm×0.5 mm were produced by punching. Upon a punched-out product with a crack, chip, or burr being judged as a defective product and a product having a smooth contour without crack, chip or burr being judged as a non-defective product, the number of non-defective products was divided by the number of punched-out products (1000) and multiplied by 100, to calculate out the pass rate (%).

Next, each of the column-shaped master solder alloys of Samples 11 to 41 and 48 to 65 is processed into balls according to the method below, by use of a liquid atomization system. As a liquid in atomization, oil, which is effective in preventing the solder from oxidation, was used. Then, using a ball thus obtained, a joined body made of a Si chip and a substrate was fabricated, and shear strength of the joined body was measured, to give the result as the first evaluation of bondability. Furthermore, by use of a ball thus obtained, a joined body made of a substrate and the solder ball was fabricated, and the void fraction of this joined body was measured, to give the result as the second evaluation of bondability. Further, for a joined body fabricated in the similar manner, the aspect ratio of the solder as wetting and spreading out was calculated out, to evaluate wettability. Furthermore, for a joined body fabricated in the similar manner, a heat cycle test was performed, and the bonding interface after the test was observed, to give the result as the evaluation of reliability. In addition, for evaluating sealability of the solder alloy, a sample sealed up with the solder alloy was made, and the leak condition was checked. The production method of balls and the respective evaluations are explained below.

### <Production Method of Balls>

Each of the prepared master alloys (columns with 27 mm diameter) of Samples 11 to 14 and 48 to 65 was charged in a nozzle of the liquid atomization system, and this nozzle was set in the upper region (inside a high-frequency melting coil) of a quartz tube containing oil heated to 310° C. After being heated to 560° C. by high frequency and maintained for 5 minutes, the master alloy in the nozzle was atomized with a pressure being applied to the nozzle by an inert gas, to form balls of the solder alloy. While the ball diameter had a set value at 0.28 mm, the diameter of the tips of the nozzle had been preliminarily adjusted. Each sample ball thus obtained was washed with ethanol three times, and then was dried for 2 hours at 45° C. in a vacuum by a vacuum dryer.

### <Shear Strength (Evaluation 1 of Bondability)>

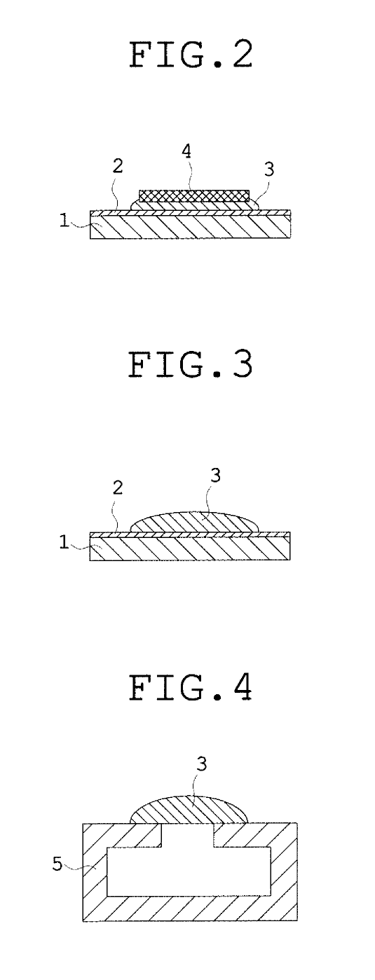

To confirm bondability of solder, with respect to each of Samples 11 to 41 and 48 to 65, a joined body of a Si chip 4 and a Cu substrate 1 (substrate thickness: 0.3 mm) plated with a Ni plating 2 (film thickness: 3.0 μm) was formed via a solder alloy 3 made of each sample, as shown in FIG. 2, and shear strength was measured by use of “XYZTEC Co., Ltd., apparatus name: Condor Sigma”. The joined body was produced by a die bonder (West Bond Corp., MODEL: 7327C). First, the heating section of the apparatus was conditioned to keep a temperature higher than the melting point of the solder sample by 40° C. while flowing a nitrogen gas, then the substrate was placed on the heating section to be heated for 15 seconds, then the sample solder was mounted thereon and heated for 20 seconds, and then the chip 3 was mounted on the molten solder and scrubbed for 3 seconds. Upon completion of the scrub, the joined body was promptly moved to the cooling section flowing with a nitrogen gas, to be cooled down to the room temperature, and was taken out into the atmosphere.

### <Measurement of Void Fraction (Evaluation 2 of Bondability)>

To evaluate bondability with respect to each of the samples 11 to 41 and 48 to 65, there was produced a joined body of a Cu substrate 1 having a plating layer 2 to which a solder alloy 3 of each sample was soldered as shown in the schematic diagram of FIG. 3 according to the following procedure, and the void fraction was measured.

A wettability testing machine (apparatus name: controlled atmosphere wettability testing machine) was activated and a nitrogen gas was flowed at the flow rate of 12 L/min from four portions around the heater section to be heated, upon the heater section being covered with a double cover. Then, the set temperature for the heater was adjusted to the temperature higher than the melting point by 50° C. and the heater was heated. After the heater temperature came to be stable at the set value, the Cu substrate (substrate thickness: 0.3 mm) plated with the Ni plating (film thickness: 3.0 μm) was set on the heater section and heated for 25 seconds, and then the ball-shaped solder alloy 3 was mounted on the Cu substrate and heated for 25 sec, to form a joined body 3 as shown in FIG. 3. Upon completion of the heating, the Cu substrate was removed from the heater section and was temporally put aside where the nitrogen atmosphere was maintained, for cooling, and then was taken out into the atmosphere after being cooled sufficiently.

Regarding the fabricated joined body, void fraction of the Cu substrate to which the solder alloy was bonded was measured by use of an X-ray transmission apparatus (manufactured by Toshiba Corporation, TOSMICRON-6125). To be specific, the joined surface of the solder alloy and the Cu substrate let X-ray transmit vertically from the upper side, and the void fraction was calculated by application of Equation 1 below. The measurement results of void fractions of the joined bodies are shown in Table 2.

Void Fraction (%)=Void Area÷(Void Area+Bonding Area between Solder Alloy and Cu Substrate)×100. [Equation 1]

### <Measurement of Aspect Ratio (Evaluation of Wettability)>

To evaluate wettability of the solder samples, with respect to each of Samples 11 to 14 and 48 to 65, a joined body similar to that fabricated for measurement of void fraction was fabricated, and aspect ratio was calculated out by application of Equation 2 below.

Aspect Ratio=Diameter of wet and spread solder÷Solder Thickness [Equation 2]

In Equation 2, “Diameter of Wet and Spread Solder” is intended to have a value calculated from the solder area on the assumption that the wet and spread solder has a round shape. “Solder Thickness” means a maximum height (thickness) of the solder when viewed from the direction forming a plane perpendicular to the surface on which the wet solder spreads. That is, a larger aspect ratio means that the solder spreads thinner and broader on the substrate, and thus has a good wetting spread property.

### <Heat Cycle Test (Evaluation of Reliability)>

To evaluate reliability of solder bonding, each of Samples 11 to 41 and 48 to 65 underwent a heat cycle test. This test was conducted upon use of a joined body composed of a Cu substrate and a Si chip bonded together via a solder alloy, as prepared in the same manner as in Evaluation 1 of bondability. First, the joined body was subject to predetermined repetitions of cycles each including cooling down to −55° C. and heating up to 260° C. Thereafter, the Cu substrate bonded with the solder alloy was embedded in a resin, underwent cross-section polishing, and was observed, for the joined surface, via SEM (manufactured by Hitachi Ltd. S-4800). A case where a peeling at the joined surface or a crack in the solder was found was ranked as “×”, and a case where the initial state of the joined interface was maintained without such a defect was ranked as “∘”.

### <Check of Leak Condition (Evaluation of Sealability)>

To check sealability with the solder alloy, with respect to each of Samples 11 to 41 and 48 to 65, a container 4 (made of ceramics evaporated with 0.1 μm Au on the joined surface) having a shape as shown in FIG. 4 was sealed with a solder alloy 3 of each sample. For sealing, a simple die bonder (West Bond Co., Ltd., MODEL: 7327C) was used, so that the sample was held in a nitrogen flow (8 L/min) for 30 seconds at a temperature higher than the melting point by 50° C., then was sufficiently cooled down to the room temperature in a nitrogen-flowed side box, and then was taken out into the atmosphere. Each sealed body thus prepared was immersed in water for two hours, then taken out of the water, and disassembled for checking of the leak condition. A case where water was inside the sealing body was judged to have a leak, and was ranked “×” as an evaluation of sealability. A case without such a leak was evaluated as “0”. The evaluation results of sealability are shown in Table 2.

TABLE 2

| | | Evaluation 2 of | | | | | | |
|---|---|---|---|---|---|---|---|---|
| | Evaluation 1 of | Processability | Evaluation 1 | | | Evaluation of | | |
| | Processability | Pass Rate (%) | of Bondability | Evaluation of | Evaluation 2 | Sealability | Evaluation of Reliability | |
| | Processability | of Punched-out | Shear Strength | Wettability | of Bondability | Check of Leak | Heat Cycle Test | |
| Sample | into Sheet | Products | (MPa) | Aspect Ratio | Void Fraction | Condition | 300 | 500 |
| 1 | ∘ | 100 | — | — | — | — | — | — |
| 2 | ∘ | 100 | — | — | — | — | — | — |
| 3 | ∘ | 100 | — | — | — | — | — | — |
| 4 | ∘ | 100 | — | — | — | — | — | — |
| 5 | ∘ | 99 | — | — | — | — | — | — |
| 6 | ∘ | 100 | — | — | — | — | — | — |
| 7 | ∘ | 100 | — | — | — | — | — | — |
| 8 | ∘ | 100 | — | — | — | — | — | — |
| 9 | ∘ | 100 | — | — | — | — | — | — |
| 10 | ∘ | 99 | — | — | — | — | — | — |
| 11 | — | — | Chip Fracture | 5.4 | 0.1 | ∘ | ∘ | ∘ |
| 12 | — | — | Chip Fracture | 5.5 | 0 | ∘ | ∘ | ∘ |
| 13 | — | — | Chip Fracture | 5.6 | 0 | ∘ | ∘ | ∘ |
| 14 | — | — | Chip Fracture | 5.6 | 0 | ∘ | ∘ | ∘ |
| 15 | — | — | Chip Fracture | 5.4 | 0 | ∘ | ∘ | ∘ |
| 16 | — | — | Chip Fracture | 5.6 | 0.1 | ∘ | ∘ | ∘ |
| 17 | — | — | Chip Fracture | 5.5 | 0 | ∘ | ∘ | ∘ |
| 18 | — | — | Chip Fracture | 5.7 | 0 | ∘ | ∘ | ∘ |
| 19 | — | — | Chip Fracture | 5.5 | 0 | ∘ | ∘ | ∘ |
| 20 | — | — | Chip Fracture | 5.6 | 0.1 | ∘ | ∘ | ∘ |
| 21 | — | — | Chip Fracture | 6 | 0 | ∘ | ∘ | ∘ |
| 22 | — | — | Chip Fracture | 6.2 | 0 | ∘ | ∘ | ∘ |
| 23 | — | — | Chip Fracture | 5.6 | 0 | ∘ | ∘ | ∘ |
| 24 | — | — | Chip Fracture | 5.7 | 0 | ∘ | ∘ | ∘ |
| 25 | — | — | Chip Fracture | 6.2 | 0 | ∘ | ∘ | ∘ |
| 26 | — | — | Chip Fracture | 6.4 | 0 | ∘ | ∘ | ∘ |
| 27 | — | — | Chip Fracture | 5.4 | 0 | ∘ | ∘ | ∘ |
| 28 | — | — | Chip Fracture | 5.6 | 0 | ∘ | ∘ | ∘ |
| 29 | — | — | Chip Fracture | 6.1 | 0 | ∘ | ∘ | ∘ |
| 30 | — | — | Chip Fracture | 6.3 | 0 | ∘ | ∘ | ∘ |
| 31 | — | — | Chip Fracture | 5.5 | 0 | ∘ | ∘ | ∘ |
| 32 | — | — | Chip Fracture | 5.7 | 0 | ∘ | ∘ | ∘ |
| 33 | — | — | Chip Fracture | 5.4 | 0 | ∘ | ∘ | ∘ |
| 34 | — | — | Chip Fracture | 5.6 | 0 | ∘ | ∘ | ∘ |
| 35 | — | — | Chip Fracture | 5.9 | 0 | ∘ | ∘ | ∘ |
| 36 | — | — | Chip Fracture | 6.1 | 0.1 | ∘ | ∘ | ∘ |
| 37 | — | — | Chip Fracture | 7.3 | 0 | ∘ | ∘ | ∘ |
| 38 | — | — | Chip Fracture | 7.4 | 0 | ∘ | ∘ | ∘ |
| 39 | — | — | Chip Fracture | 6.1 | 0 | ∘ | ∘ | ∘ |
| 40 | — | — | Chip Fracture | 6.1 | 0 | ∘ | ∘ | ∘ |
| 41 | — | — | Chip Fracture | 7.4 | 0 | ∘ | ∘ | ∘ |
| *42 | x | 50 | — | — | — | — | — | — |
| *43 | x | 52 | — | — | — | — | — | — |
| *44 | Δ | 65 | — | — | — | — | — | — |
| *45 | x | 50 | — | — | — | — | — | — |
| *46 | ∘ | 89 | — | — | — | — | — | — |
| *47 | Δ | 63 | — | — | — | — | — | — |
| *48 | — | — | 50 | 4 | 8 | x | x | — |
| *49 | — | — | 52 | 3.2 | 9.6 | x | x | — |
| *50 | — | — | 51 | 3.5 | 11.2 | x | x | — |
| *51 | — | — | 48 | 2.6 | 8 | x | x | — |
| *52 | — | — | Chip Fracture | 4 | 0.8 | ∘ | ∘ | ∘ |
| *53 | — | — | Chip Fracture | 3.8 | 0.7 | ∘ | ∘ | ∘ |
| *54 | — | — | 51 | 2.4 | 8 | x | x | — |
| *55 | — | — | 50 | 3.3 | 7.5 | x | x | — |
| *56 | — | — | 52 | 3.2 | 8.3 | x | x | — |
| *57 | — | — | 51 | 2.6 | 9.6 | x | x | — |
| *58 | — | — | 48 | 2.2 | 10.3 | x | x | — |
| *59 | — | — | 50 | 2.4 | 8.7 | x | x | — |
| *60 | — | — | 49 | 2.1 | 9.4 | x | x | — |
| *61 | — | — | 52 | 3.5 | 8.9 | x | x | — |
| *62 | — | — | 53 | 3.2 | 10.4 | x | x | — |
| *63 | — | — | 51 | 2.8 | 9.3 | x | x | — |
| *64 | — | — | 52 | 2.2 | 8.1 | x | x | — |
| *65 | — | — | 50 | 4 | 11.3 | x | x | — |

(Note)
Sample marked with in the table are reference examples.

As can be seen from Table 2, each solder alloy of Samples 1 to 41 of the present invention showed excellent characteristics in each evaluation item. That is, in the evaluation of processability into sheet, any defect such as a crack was not found, and the pass rate of punch-out products was 99% or more, which is a very high pass rate. Further, in the shear strength measurement, every measured sample caused fracture of the chip, from which a firm bonding was confirmed. In addition, in the aspect ratio measurement, which involved evaluation of wettability, every measured sample showed a high value, or 5.4 or greater. Further, in the void fraction measurement, which involves evaluation of bondability, voids rarely ware generated. Further, in the evaluation of sealability, leak never occurred. Furthermore, in the heat cycle test, which involved evaluation of reliability, a failure did not occur until 500 cycles for all the samples. The reason why such good results were obtained is in that each solder alloy of Samples 1 to 41 satisfied the composition range of the present invention, which is near the ternary eutectic point of Au, Sn and Ag. Regarding Samples 1 to 41 of the present invention, upon embedding in resin and cross-section polishing being carried out, cross-sectional observation by SEM was conducted, to be confirmed that 90 vol % or more of the metal structure was lamellar structure.

In addition, the shear test resulted in fracture of the chip for every tested sample, from which a firm bonding was confirmed. Further, each of Samples 21 and 22, which contained Al, Samples 25 and 26, which contained Ge, Samples 29 and 30, which contained Mg and Samples 37 and 38, which contained P, showed good wetting and spreading property by aspect ratio of 6.0 or greater. As demonstrated by these good results, it has been confirmed that the solder alloy of the present invention is excellent in various properties while having a melting point that has not yet achieved by conventional Pb-free solder.

On the other hand, each solder alloy of Samples 42-65, which were reference examples, was given unfavorable result at least in one of the items. In other words, in the evaluation of sheet processability, many samples generated cracks, and the pass rate of punched-out products, which involved evaluation of processability, was 89% at the most. Further, in the shear strength measurement, most of the samples had values as much as 50 MPa. Further, in the aspect ratio measurement, which involved evaluation of wettability, they were given very low values, or 4.0 or less. Regarding the void fraction, 0.7 to 11% were resulted, or voids were generated at a significant rate. In the heat cycle test as evaluation of reliability, failures occurred before 300 cycles for every sample except Samples 52 and 53. Defects about leak were generated for every sample except Samples 52 and 53 also in the evaluation of sealability.

Further, Au content of the solder alloy of the present invention is not more than 64.5 wt %, which is significantly lower than that %f 80 mass % Au-20mass % alloy or 87.5 wt % Au-12.5 mass % Ge alloy, thereby realizing cost reduction.

As discussed above, the solder alloy of the present invention has excellent features in various properties at a low cost, and due to the low melting point in comparison with Au—Ge alloys, for example, is very easy to use, to facilitate safety in production.

### DESCRIPTION OF THE REFERENCE SYMBOLS

1 Cu substrate

2 Ni plating layer

3 solder alloy

4 Si chip

5 sealed container

1. An Au—Sn—Ag based solder alloy, characterized by:
containing Sn of 27.5 mass % or more but less than 33.0 mass %; and
containing Ag of 8.0 mass % or more but 14.5 mass % or less,
wherein a balance is made up by Au except for elements that are inevitably contained owing to a procedure for manufacturing.

2. The Au—Sn—Ag based solder alloy according to claim 1, characterized by further containing one or more elements out of Al, Cu, Ge, In, Mg, Ni, Sb, Zn and P,
wherein, if Al is contained, a content thereof is 0.01 mass % or more but 0.8 mass % or less; if Cu is contained, a content thereof is 0.01 mass % or more but 1.0 mass % or less; if Ge is contained, a content thereof is 0.01 mass % or more but 1.0 mass % or less; if In is contained, a content thereof is 0.01 mass % or more but 1.0 mass % or less; if Mg is contained, a content thereof is 0.01 mass % or more but 0.5 mass % or less; if Ni is contained, a content thereof is 0.01 mass % or more but 0.7 mass % or less; if Sb is contained, a content thereof is 0.01 mass % or more but 0.5 mass % or less; if Zn is contained, a content thereof is 0.01 mass % or more but 5.0 mass % or less; and if P is contained, a content thereof is 0.500 mass % or less.

3. The Au—Sn—Ag based solder alloy according to claim 1, characterized by:
containing Sn of 29.0 mass % or more but 32.0 mass % or less; and
containing Ag of 10.0 mass % or more but 14.0 mass % or less.

4. The Au—Sn—Ag based solder alloy according to claim 1,
characterized in that at least a part of a metallic structure is a lamellar structure.

5. The Au—Sn—Ag based solder alloy according to claim 1,
characterized in that a metallic structure is a lamellar structure and occupies 90 vol % or more.

6. An electronic component characterized by being sealed up by use of the Au—Sn—Ag based solder alloy according to claim 1.

7. An electronic component mounting device characterized by mounting thereon the electronic component according to claim 6.
